(19) United States
(12) Patent Application Publication
(10) Pub. No.: US 2010/0255346 A1
(43) Pub. Date: Oct. 7, 2010

(54) COATINGS TO INHIBIT FORMATION OF DEPOSITS FROM ELEVATED TEMPERATURE CONTACT WITH HYDROCARBONS

(76) Inventors: ORHAN ALTIN, PEORIA, IL (US); SEMIH ESER, STATE COLLEGE, PA (US); RAMYA VENKATARAMAN, LONDON (GB)

Correspondence Address: KRIEG DEVAULT LLP, ONE INDIANA SQUARE, SUITE 2800, INDIANAPOLIS, IN, 46204-2079, US

(21) Appl. No.: 12/521,954

(22) Filed: Jul. 1, 2009

Related U.S. Application Data
(63) Continuation of application No. PCT/US2008/000019, filed on Jan. 3, 2008.
(60) Provisional application No. 60/878,481, filed on Jan. 3, 2007.

(51) Int. Cl. B32B 9/00; C23C 16/18; B05D 3/04

(52) U.S. Cl. 428/701; 427/419.3; 427/404; 427/255.31; 427/377; 427/331

(57) ABSTRACT

Certain embodiments are unique coatings. Other embodiments include apparatuses, articles, and components including such coatings and, systems and methods for providing such coatings. Further embodiments, forms, objects, features, advantages, aspects, and benefits shall become apparent from the following description and drawings.

### CROSS REFERENCE

This application claims the benefit of U.S. Patent Application No. 60/878,481, filed Jan. 3, 2007, which is incorporated herein by reference.

### TECHNICAL FIELD

The technical filed relates generally to coatings to inhibit formation of deposits on surfaces which come into elevated temperature contact with hydrocarbons.

### BACKGROUND

Hydrocarbon fluids which come into contact with metal or alloy surfaces at elevated temperatures tend to form deposits. These deposits are problematic for systems such as gas turbine engines which utilize fuels and lubricants including one or more hydrocarbon fluids such as hydrocarbon liquids, vapors, particles or combinations thereof. Hydrocarbon fluids may include sulfur and other heteroatom compounds such as oxygen and nitrogen. Hydrocarbon fluids may also include a number of additives such as antioxidants, metal deactivators, antifreeze, and/or anti-corrosion additives. During gas turbine engine operation, oxidative, thermal and catalytic degradation products of hydrocarbons and heteroatom compounds may produce undesired deposits. Oxidative degradation can lead to the formation of large polymers and gum/lacquer like deposits. Thermal degradation can lead to the formation of soot-like and pyrolytic deposits. Catalytic degradation can lead to the formation of filamentous and laminar graphite-like deposits. Deposits can be formed by metal-assisted decomposition of hydrocarbons, and condensation and polymerization of the hydrocarbon species can give rise to large polyaromatic hydrocarbons (PAHs), carbonaceous solids, and solid carbon. Solid deposits also include metal sulfides formed due to the interaction or reaction of metal and alloy surfaces with sulfur compounds present in hydrocarbon fluids. Deposits formed by the foregoing and other mechanisms create a variety of problems for metal and alloy surfaces which come into contact with hydrocarbon fluids at elevated temperatures. For example, fuel injectors, fuel lines and other components of fuel systems can experience valve malfunctions, injector plugging, injector wall fouling and other problems due to deposits. Lubrication systems may experience clogging of vent pipes and other components by deposits which can impede flow of oil through the system and prevent cool down of bearings and other hot surfaces. These and other problems are expensive and can result in inefficiency, malfunction, and even failure.

### SUMMARY

Certain embodiments are unique coatings. Other embodiments include apparatuses, articles, and components including such coatings and, systems and methods for providing such coatings. Further embodiments, forms, objects, features, advantages, aspects, and benefits shall become apparent from the following description and drawings.

### BRIEF DESCRIPTION OF THE DRAWINGS

FIG. 1 is a sectional view of a portion of a coated substrate.

FIG. 2 is a sectional view of a portion of a coated substrate.

FIG. 3 is a flow diagram of operations in a substrate coating method.

FIG. 4 is a schematic diagram of a system for performing a coating operation.

FIG. 5A is a field emission scanning electron microscopy image of an uncoated substrate surface.

FIG. 5B is a field emission scanning electron microscopy image of a coated substrate surface.

FIG. 6 is a graph illustrating temperature programmed oxidation profiles of deposits on coated and uncoated substrates.

### DETAILED DESCRIPTION

For the purposes of promoting an understanding of the principles of the invention, reference will now be made to the embodiments illustrated in the drawings and specific language will be used to describe the same. It will nevertheless be understood that no limitation of the scope of the invention is thereby intended, such alterations and further modifications in the illustrated embodiments, and such further applications of the principles of the invention as illustrated therein being contemplated as would normally occur to one skilled in the art to which the invention relates.

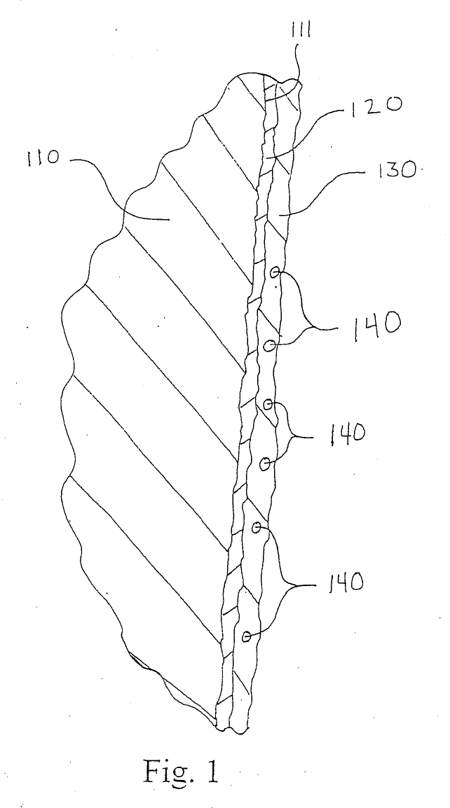

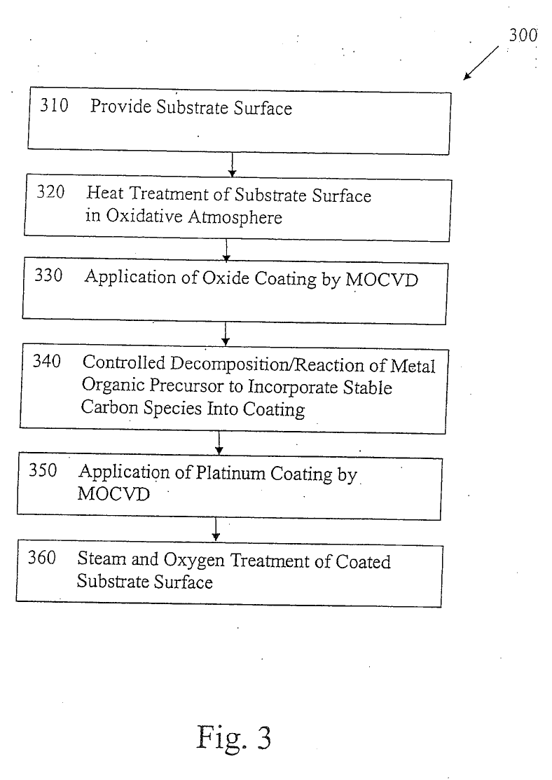

With reference to FIG. 1, there is illustrated a portion of a substrate 110 having a surface 111, a first metal oxide coating layer 120, and a second metal oxide coating layer 130 which includes a number of stable carbon species 140. Substrate 110 is preferably a metal or alloy material, for example, but not limited to, stainless steels, metals including Al, Co, Cr, Fe, Mo, Ni, Ti, W and alloys thereof, and other metals and alloys employed in gas turbine engines. First metal oxide coating layer 120 is preferably a layer of Cr₂O₃ which has been formed on surface 111 by heating substrate 110 to oxidize chromium present in substrate 110. It is also contemplated that first metal oxide coating layer 120 could include one or more other types of metal oxides including, for example, oxides of the metals and alloys described above and/or formed in other manners such as those described below in connection with FIG. 3.

Second metal oxide coating layer 130 is preferably a layer of Al₂O₃ which has been formed on first metal oxide coating layer 120 by a chemical deposition technique, preferably by a chemical vapor deposition technique, most preferably by a metal organic chemical vapor deposition technique. In additional embodiments, second metal oxide coating layer 130 could include a variety of other materials, for example, SiO₂, TiO₂, ZrO₂, Cr₂O₃, Ta₂O₅, WO₂, MoO₂, a ternary oxide of Aluminum-Magnesium, a ternary oxide of Aluminum-Potassium, and combinations thereof with one another or with Al₂O₃. Further embodiments also contemplate that other chemical deposition techniques such as pulsed laser deposition, physical vapor deposition, electron beam physical vapor deposition, effusive chemical vapor deposition and others could be used.

Stable carbon species 140 are preferably present in second metal oxide coating layer 130 and are preferably formed through the partial decomposition of a metal organic precursor that leaves carbon associated with the metal oxide coating. Preferred stable carbon species include C—C, C—O, C═O, and/or COOR as constituents which may be present in a variety of forms and bonded with a variety of additional molecular constituents. A number of variations on the embodiment illustrated in FIG. 1 are contemplated. For example, first metal oxide coating layer 120 might be absent, first metal oxide coating layer 120 and/or second metal oxide coating layer 130 might have different compositions or be formed by different techniques from those described above, and stable carbon species might be present in differing quantities or might be absent.

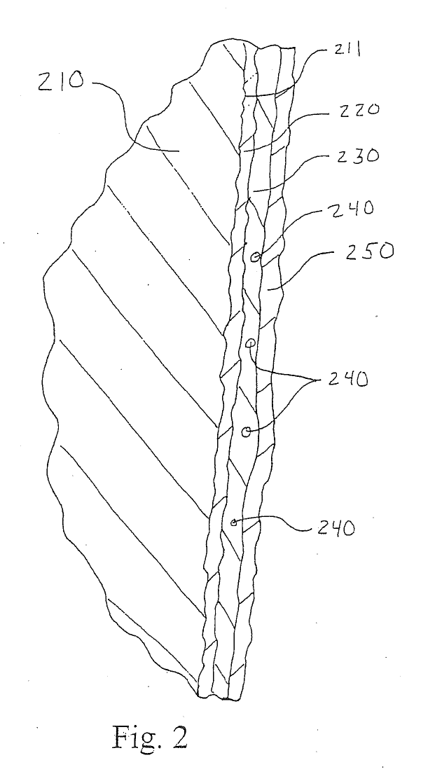

With reference to FIG. 2, there is illustrated a portion of a substrate 210 having a surface 211, a first metal oxide coating layer 220, and a second metal oxide coating layer 230 which includes a number of stable carbon species 240, and platinum layer 250. Substrate 210 is preferably a metal or alloy material, for example, but not limited to, stainless steels, metals including Al, Co, Cr, Fe, Mo, Ni, Ti, W and alloys thereof, and other metals and alloys employed in gas turbine engines. First metal oxide coating layer 220 is preferably a layer of Cr₂O₃ which has been formed on surface 211 by heating substrate 210 to oxidize chromium present in substrate 210. It is also contemplated that first metal oxide coating layer 220 could include one or more other types of metal oxides including, for example, oxides of the metals and alloys described above and/or formed in other manners such as those described below in connection with FIG. 3.

Second metal oxide coating layer 230 is preferably a layer of Al₂O₃ which has been formed on first metal oxide coating layer 220 by a chemical deposition technique, preferably by a chemical vapor deposition technique, most preferably by a metal organic chemical vapor deposition technique. In additional embodiments, second metal oxide coating layer could include a variety of other materials, for example, SiO₂, TiO₂, ZrO₂, Cr₂O₃, Ta₂O₅, WO₂, MoO₂, a ternary oxide of Aluminum-Magnesium, a ternary oxide of Aluminum-Potassium, and combinations thereof with one another or with Al₂O₃. Further embodiments also contemplate that other chemical deposition techniques such as pulsed laser deposition, physical vapor deposition, electron beam physical vapor deposition, effusive chemical vapor deposition and others could be used.

Platinum coating layer 250 is preferably formed on second metal oxide coating layer 230 by a metal organic chemical vapor deposition technique, but could also be formed using other techniques such as the chemical deposition techniques described above. Stable carbon species 240 are preferably disposed in second metal oxide coating layer 230 through the partial decomposition of a metal organic precursor that leaves carbon associated with the metal oxide coating. Preferred stable carbon species include C—C, C—O, C═O, and/or COOR as constituents which may be present in a variety of forms and bonded with a variety of additional molecular constituents. A number of variations on the embodiment illustrated in FIG. 2 are contemplated. For example, first metal oxide coating layer 220 might be absent, first metal oxide coating layer 220 and/or second metal oxide coating layer 230 might have different compositions or be formed by different techniques from those described above, platinum coating layer might be of a different catalytic material or absent altogether, and stable carbon species might be present in differing quantities or distributions or might be absent.

The coated substrates described above in connection with FIGS. 1 and 2 are preferably used to inhibit or prevent the formation of deposits on surfaces which come into contact with hydrocarbons at high temperatures. In certain preferred embodiments, a coated substrate such as described above is provided in a fuel system for a gas turbine engine. In these embodiments, the surfaces of fuel pipes, fuel passageways and/or injector nozzles of gas turbine engine fuel systems which would otherwise be exposed to fuel or other hydrocarbon fluids at elevated temperatures are provided with coatings such as those described above. In other preferred embodiments, a coated substrate such as described above is provided in a lubrication system for a gas turbine engine. In these embodiments, the surfaces of gas turbine engine components that would otherwise be exposed to lubricants or other hydrocarbon fluids are provided with coatings such as those described above. In further embodiments, a variety of additional substrate surfaces which would otherwise come into contact with hydrocarbon fluids at elevated temperatures are provided with coatings such as those described above. The surfaces to be coated often have complex geometries, for example, the fuel passageways of gas turbine engine fuel pipes and fuel injectors. The coatings described above can be provided on complex geometries by methods and techniques such as the preferred methods and techniques described below.

With reference to FIG. 3 there is illustrated a flow diagram 300 of operations of a preferred method of coating a substrate. Flow diagram 300 begins at operation 310 where a substrate surface is provided. The substrate surface could be any metal or alloy surface, for example, stainless steels, metals including Al, Co, Cr, Fe, Mo, Ni, Ti, W and alloys thereof, and other metals and alloys employed in gas turbine engines. Flow diagram 300 then proceeds to operation 320 where heat treatment of the substrate surface occurs in an oxidative atmosphere. The heat treatment of a stainless steel substrate preferably occurs at temperatures between 300-500° C. The heat treatment is applied for a time and temperature sufficient to cause chromium in the stainless steel substrate to diffuse toward the substrate surface and form a protective chromium oxide rich layer. In the case of substrate materials not including chromium, an oxide rich layer can be formed by oxidation of other metal, for example, heat treatment of Ni-based superalloys at about 800° C. can produced oxide rich surface layers such as Al₂O₃, TiO₂, Cr₂O₃, Fe₂O₃ and NiO. The required time and temperature will depend upon the composition of the substrate, the nature of the oxidative atmosphere, and other factors. This layer may provide improved diffusion stability of the coating, enhance bonding of an alumina coating subsequently applied to the substrate, and prevent refractory transition elements such as molybdenum, vanadium and tungsten from diffusing into the coating layer. When combined with a subsequently applied coating layer, the multi-layer coatings may also provide better coverage of the surface compared to a single coating layer. Forming an oxide rich layer by heat treatment can also provide a multi-material and/or multi-layer coating without requiring two metal organic chemical vapor deposition operations. It should be appreciated, however, that not every embodiment need exhibit the foregoing characteristics, and that in certain embodiments the heat treating operation may be omitted or replaced with alternate processes.

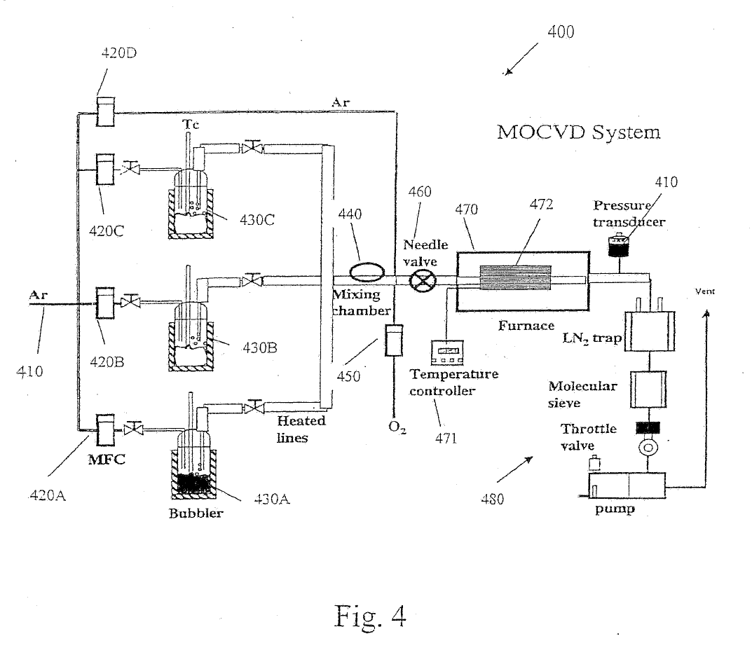

At operation 330, a metal oxide coating is applied to the substrate surface most preferably by using a metal organic chemical vapor deposition technique. In a preferred embodiment, aluminum 2,4 pentanedionate is used at the metal organic precursor to form an aluminum oxide coating layer. It should be appreciated, however, that a variety of other precursor materials can be used, and that a variety of other oxide coating layers can be provided from a variety of other metal organic precursors. Further details of a system for metal organic chemical vapor deposition are described below in connection with FIG. 4. It should also be appreciated that the formation of an oxide layer can be accomplished using a variety of other techniques, such as pulsed laser deposition, physical vapor deposition, electron beam physical vapor deposition, effusive chemical vapor deposition and others.

At operation 340 a controlled decomposition or reaction of the metal organic precursor is performed to incorporate stable carbon species into the oxide layer being formed by metal organic chemical vapor deposition. In certain preferred embodiments oxygen is introduced and/or reacted with one or more organometallic compounds. By varying the temperature, pressure, carrier gas flow rate and duration of coating the nucleation and subsequent growth of thin films on the metal substrate can be controlled so as to obtain metal oxide coatings with varying thickness, phase properties and variant physical and chemical properties, including the incorporation of stable carbon species in the coating. The presence of these carbon species can stabilize acid sites on metal oxide surfaces and inhibit the diffusion of carbon containing species through the oxide, however, these characteristics need not be present in all embodiments.

At operation 350, a thin layer of platinum is applied preferably by using a metal organic chemical vapor deposition system such as that described below in connection with FIG. 4, or by one of the alternative techniques described above. In a preferred embodiment, platinum 2,4 pentanedionate is used at the metal organic precursor to form the platinum layer. The layer of platinum can serve as a barrier that prevents substrate metal migration, and can provide catalytic activity for the oxidation of carbonaceous deposits that might be formed on the coated substrate. In a preferred embodiment where a coating is formed in the fuel system of a gas turbine engine, any carbonaceous solids formed in one engine cycle can be removed upon engine shut down when the surface of the metal is still exposed to a high temperature and an oxidative environment but without any inflow of hydrocarbons. In this embodiment the coating exhibits a self-cleaning characteristic. It should be understood that these characteristics need not be present in all embodiments, and that certain embodiments may omit application of a layer of platinum. It should also be understood that a catalyst other than platinum can be used.

At operation 360, oxygen and/or steam treatment of the coated substrate are performed. Treatment with oxygen and/or steam may cause further oxidation which may aid in passivation of any active sites present on the coated surface and may further improve the quality of the coating leading to substantial elimination or improved minimization of carbon deposits which would otherwise tend to form on the coated surfaces. It should be understood that these characteristics need not be present in all embodiments, and that certain embodiments may omit the oxygen and/or steam treatment.

With reference to FIG. 4 there is illustrated a metal organic chemical vapor deposition system 400 useful for applying coatings to a substrate. Gas input 410 provides a carrier gas such as argon to the system. Mass flow controllers 420A, 420B, 420C, and 420D control passage of the carrier gas through the system. Mass flow controllers 420A, 420B, and 420C control gas flow to bubblers 420A, 420B, and 420C, respectively. Output from the mass flow controllers can be regulated by valves (not numbered). Bubblers 420A, 420B, and 420C heat liquid metal organic precursor materials to provide metal organic precursor vapors which are transported through the system by the carrier gas. In a preferred embodiment one bubbler provides aluminum 2,4 pentanedionate vapor for forming an aluminum oxide coating and another bubbler provides platinum 2,4 pentanedionate vapor for forming a platinum coating layer. Output from the bubblers is regulated by valves (not numbered). The output from bubblers passes through heated lines (not numbered). When the output from multiple bubblers is to be mixed, this operation can occur in mixing chamber 440 which can receive the output of each of the bubblers 430A, 430B, and 430C. The output of mixing chamber 440 passes through needle valve 460 and to an environment including a substrate to be coated 472, which is contained in furnace 470 which is controlled by temperature controller 471 and whose pressure can be monitored by pressure transducer 473. Argon from mass flow controller 420D and oxygen from mass flow controller 450 can also be introduced after mixing chamber 440 and before needle valve 440. In furnace 470 the decomposition of the metal organic precursor is controlled by varying the coating temperature, pressure, time, carrier gas flow-rate and concentration of precursor vapors in the carrier gas. Furnace 470 outputs to a cleaning system 480 which includes an LN₂ trap, a molecular sieve, a throttle valve, a pump and a vent.

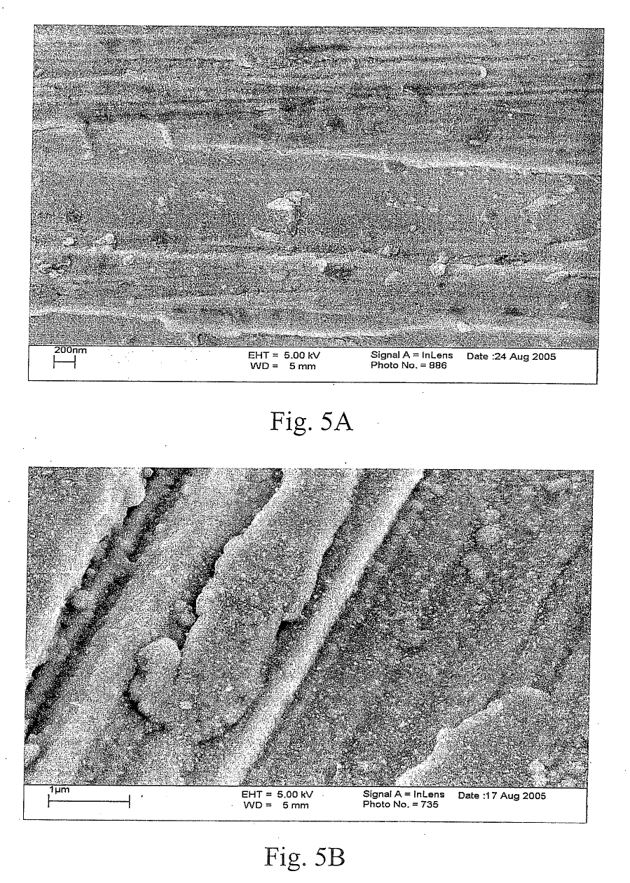

With reference to FIG. 5A there is illustrated a filed emission scanning electron microscopy image of an uncoated stainless steel SS316 substrate. With reference to FIG. 5B there is illustrated a filed emission scanning electron microscopy image of a stainless steel SS316 substrate with an aluminum oxide coating. Measurements of the coating thickness for two samples are shown in Table 1 below.

TABLE 1
Thickness of CVD Alumina Coatings Measured by Ellipsometry
Thickness (nm)

| Sample name | Min. | Max. |
|---|---|---|
| Al₂O₃ coating on SS316-1 | 34 | 133.5 |
| Al₂O₃ coating on SS316-2 | 62 | 164.3 |

FIG. 5A shows the roughness of the uncoated SS316 substrate surface. FIG. 5B shows that the alumina coating applied to this surface is made of more or less uniform spherical structures and that the coating reproduces the surface finish of the underlying substrate to a large extent. These results shown above in Table 1 vary along the length of the substrate as well as between two samples coated under the same conditions. This variation can be explained by the surface roughness of the uncoated substrates which is also reflected in the coating. Since the accuracy of ellipsometry depends upon samples that are perfectly flat and fully reflective, and the samples used in his study do not have these properties, measurement error accounts for a large degree of the variation in coating thickness.

The results of an X-ray photoelectron spectroscopy (XPS) characterization are given below in Table 2.

TABLE 2
XPS Determined Chemical Composition of Alumina Coated
Surfaces of Two SS316 Substrates Coated Under the
Same Conditions
Surface Chemical Composition (relative atomic %)

| Sample name | Al | C | O | N | B | S | Na | Zn | F |
|---|---|---|---|---|---|---|---|---|---|
| Al₂O₃ on SS316-1 | 20.2 | 30.7 | 46.6 | 0.4 | 0.6 | 0.3 | 0.2 | 0.0 | 1.0 |
| Al₂O₃ on SS316-2 | 26.7 | 18.1 | 53.1 | 0.3 | 0.2 | 0.7 | 0.6 | 0.2 | 0.1 |

In one embodiment the surface chemical composition determined by XPS characterization and expressed in relative atomic percent includes about 18% carbon. In another embodiment the surface chemical composition determined by XPS characterization and expressed in relative atomic percent includes about 30% carbon. In additional embodiments the surface chemical composition determined by XPS characterization and expressed in relative atomic percent includes about 10% or more carbon. In additional embodiments the surface chemical composition determined by XPS characterization and expressed in relative atomic percent includes about 15% or more carbon. In additional embodiments the surface chemical composition determined by XPS characterization and expressed in relative atomic percent includes about 18% or more carbon. The average Al:O ratio was 0.45. The decrease in ratio of alumina to oxygen compared to pure Al₂O₃ is attributed to the presence of significant amounts of carbon species (from the precursor) and other minor impurities in the coating.

Curve fitting results of the C 1s spectra obtained from the XPS analysis of the alumina coatings gave preliminary information on the nature of the carbon species present in the coatings. These results are shown in Table 3.

TABLE 3
Nature and Relative Atomic Ratios of Carbon Species Present in the
Coating
Nature of Carbon Species
(relative atomic %)

| | | | | |
|---|---|---|---|---|
| Sample name | C—C | C—O | C═O | COOR |

| | | | | |
|---|---|---|---|---|
| Al₂O₃ on SS316-1 | 59.0 | 12.2 | 15.0 | 12.2 |
| Al₂O₃ on SS316-2 | 63.8 | 15.6 | 4.1 | 15.0 |

The effectiveness of the coating was tested by comparing the nature and amount of carbonaceous solids formed on the coated surface with that of an uncoated SS316 surface. The solid deposits on the two surfaces were formed by stressing Jet A in a ¼-inch OD flow reactor at 470° C. and 500 psi for 5 hrs. The fuel flow rate was maintained at 4 ml/min. Temperature Programmed Oxidation (TPO) was used to characterize the carbonaceous solids on the basis of their structure and oxidation reactivity. For this purpose, the deposited samples were placed in a quartz boat and heated from 100 to 900° C. under a flowing stream of O₂, the flow rate of which was maintained at 750 cc/min.

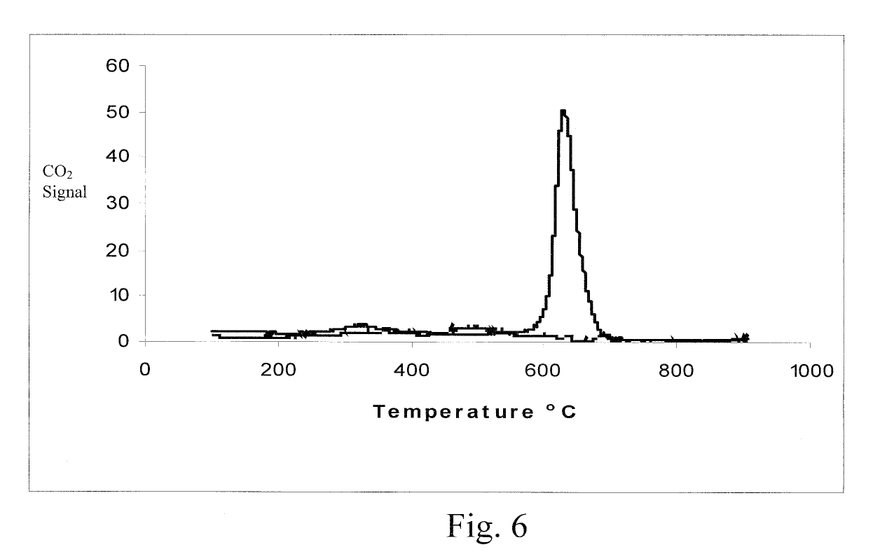

FIG. 6 illustrates the TPO profiles of the carbonaceous deposits formed on both bare SS316 and coated surfaces. The y-axis in the plot on FIG. 6 represents arbitrary units proportional to the amount of carbon dioxide evolution. From the comparison of the two profiles, it is evident that the alumina coating nearly eliminates solid formation. Inspection of the foils after thermal stressing also showed that the coating was intact at least up to 500° C. Similar coating were also found to be effective against the oxidative degradation of jet fuel as well as synthetic ester based lubricating oils.

Certain embodiments are coatings for a hydrocarbon fluid containment component including a first metal oxide layer on the component, and a second metal oxide layer on the first metal oxide layer, where the second metal oxide layer contains stable carbon species. Some embodiments further include a platinum layer on the second metal oxide layer. In some embodiments the stable carbon species include carbon constituents selected from the group consisting of C—C, C—O, C═O, and COOR. In some embodiments the second metal oxide layer includes at least one of Al₂O₃, SiO₂, TiO₂, ZrO₂, Cr₂O₃, Ta₂O₅, WO₂, MoO₂, a ternary oxide of Aluminum-Magnesium, and a ternary oxide of Aluminum-Potassium. In some embodiments the component is a gas turbine engine fuel containment component. In some embodiments the second metal oxide layer consists essentially of stable carbon species and at least one of Al₂O₃, SiO₂, TiO₂, ZrO₂, Cr₂O₃, Ta₂O₅, WO₂, MoO₂, a ternary oxide of Aluminum-Magnesium, a ternary oxide of Aluminum-Potassium, and a combination thereof with the balance being impurities. In some embodiments the stable carbon species are derived from partial decomposition of one or more organometallic compounds. In some embodiments the stable carbon species are derived from partial decomposition of aluminum 2,4-pentanedionate. In some embodiments the coating has a composition measured by XPS characterization and expressed in relative atomic percent of about 10% or more carbon. In some embodiments the coating has a composition measured by XPS characterization and expressed in relative atomic percent of about 18% or more carbon. In some embodiments the first metal oxide layer is formed by heating the component in an oxidative environment. In some embodiments the second metal oxide layer is formed by chemical vapor deposition. In some embodiments the carbon constituents of the stable carbon species consist essentially of C—C, C—O, C═O, COOR, or a combination thereof.

Certain embodiments are methods of coating a hydrocarbon fluid containment article including providing a hydrocarbon fluid containment article having a surface, providing a first metal oxide layer on the surface, and providing a second layer on the first metal oxide layer, the second layer including metal oxide and stable carbon species. Some embodiments further include providing a platinum layer on the second layer. In some embodiments the hydrocarbon fluid containment article is a gas turbine engine component. In some embodiments providing a first metal oxide layer includes oxidizing the surface of the containment article. In some embodiments providing a second layer includes performing a chemical vapor deposition. In some embodiments providing a second layer includes partial decomposition of an organometallic precursor effective to deposit metal oxide and stable carbon species on the first metal oxide layer. Some embodiments further include treating the article with steam, or oxygen, or both after the providing a second layer on the first metal oxide layer. Some embodiments further include treating the article with steam, or oxygen, or both after the providing a platinum layer on the second metal oxide layer. In some embodiments the metal oxide of the second layer is Al₂O₃, SiO₂, TiO₂, ZrO₂, Cr₂O₃, Ta₂O₅, WO₂, MoO₂, a ternary oxide of Aluminum-Magnesium, a ternary oxide of Aluminum-Potassium, or a combination thereof.

Certain embodiments are coating systems for a substrate including a first coating on the substrate, the first coating including metal oxide, a second coating on the first coating, the second coating including metal oxide and stable carbon species, and a third coating on the second coating the third coating including a hydrocarbon catalyst. In some embodiments the first coating consists essentially of metal oxide. In some embodiments the first coating is formed by oxidizing a constituent of the substrate. In some embodiments the first coating consists essentially of Cr₂O₃. In some embodiments the second coating consists essentially of metal oxide and stable carbon species with the balance being impurities. In some embodiments the second coating is formed by partial decomposition of an organometallic precursor effective to provide metal oxide and stable carbon species. In some embodiments the partial decomposition of an organometallic precursor is includes reacting oxygen with the organometallic precursor. In some embodiments the stable carbon species are effective to stabilize acid sites in the coating system. In some embodiments the stable carbon species are effective to inhibit diffusion of other carbon containing species through the coating system. In some embodiments the hydrocarbon catalyst includes platinum or palladium. In some embodiments the hydrocarbon catalyst includes a transition metal. In some embodiments the hydrocarbon catalyst is platinum.

While the invention has been illustrated and described in detail in the drawings and foregoing description, the same is to be considered as illustrative and not restrictive in character, it being understood that only the preferred embodiments have been shown and described and that all changes and modifications that come within the spirit of the inventions are desired to be protected. It should be understood that while the use of words such as preferable, preferably, preferred or more preferred utilized in the description above indicate that the feature so described may be more desirable, it nonetheless may not be necessary and embodiments lacking the same may be contemplated as within the scope of the invention, the scope being defined by the claims that follow. In reading the claims, it is intended that when words such as “a,” “an,” “at least one,” or “at least one portion” are used there is no intention to limit the claim to only one item unless specifically stated to the contrary in the claim. When the language “at least a portion” and/or “a portion” is used the item can include a portion and/or the entire item unless specifically stated to the contrary.

What is claimed is:

1. A coating for a hydrocarbon fluid containment component comprising:
a first metal oxide layer on the component; and
a second metal oxide layer on the first metal oxide layer; wherein
the second metal oxide layer contains stable carbon species.

2. The coating of claim 1 further comprising a platinum layer on the second metal oxide layer.

3. The coating of claim 1 wherein the stable carbon species include carbon constituents selected from the group consisting of C—C, C—O, C═O, and COOR.

4. The coating of claim 1 wherein the second metal oxide layer includes at least one of Al₂O₃, SiO₂, TiO₂, ZrO₂, Cr₂O₃, Ta₂O₅, WO₂, MoO₂, a ternary oxide of Aluminum-Magnesium, and a ternary oxide of Aluminum-Potassium.

5. The coating of claim 1 wherein the component is a gas turbine engine fuel containment component.

6. The coating of claim 1 wherein the second metal oxide layer consists essentially of stable carbon species and at least one of Al₂O₃, SiO₂, TiO₂, ZrO₂, Cr₂O₃, Ta₂O₅, WO₂, MoO₂, a ternary oxide of Aluminum-Magnesium, a ternary oxide of Aluminum-Potassium, and a combination thereof with the balance being impurities.

7. The coating of claim 1 wherein the stable carbon species are derived from partial decomposition of one or more organometallic compounds.

8. The coating of claim 1 wherein the stable carbon species are derived from partial decomposition of aluminum 2,4-pentanedionate.

9. The coating of claim 1 having a composition measured by XPS characterization and expressed in relative atomic percent of about 10% or more carbon.

10. The coating of claim 1 having a composition measured by XPS characterization and expressed in relative atomic percent of about 18% or more carbon.

11. The coating of claim 1 wherein the first metal oxide layer is formed by heating the component in an oxidative environment.

12. The coating of claim 1 wherein the second metal oxide layer is formed by chemical vapor deposition.

13. The coating of claim 1 wherein the carbon constituents of the stable carbon species consist essentially of C—C, C—O, C═O, COOR, or a combination thereof.

14. A method of coating a hydrocarbon fluid containment article comprising:
providing a hydrocarbon fluid containment article having a surface;
providing a first metal oxide layer on the surface; and
providing a second layer on the first metal oxide layer, the second layer including metal oxide and stable carbon species.

15. The method of claim 14 further comprising providing a platinum layer on the second layer.

16. The method of claim 14 wherein the hydrocarbon fluid containment article is a gas turbine engine component.

17. The method of claim 14 wherein the providing a first metal oxide layer includes oxidizing the surface of the containment article.

18. The method of claim 14 wherein providing a second layer includes performing a chemical vapor deposition.

19. The method of claim 14 wherein providing a second layer includes partial decomposition of an organometallic precursor effective to deposit metal oxide and stable carbon species on the first metal oxide layer.

20. The method of claim 14 further comprising treating the article with steam, or oxygen, or both after the providing a second layer on the first metal oxide layer.

21. The method of claim 15 further comprising treating the article with steam, or oxygen, or both after the providing a platinum layer on the second metal oxide layer.

22. The method of claim 14 wherein the metal oxide of the second layer is Al₂O₃, SiO₂, TiO₂, ZrO₂, Cr₂O₃, Ta₂O₅, WO₂, MoO₂, a ternary oxide of Aluminum-Magnesium, a ternary oxide of Aluminum-Potassium, or a combination thereof.

23. A coating system for a substrate comprising:
a first coating on the substrate, the first coating including metal oxide;
a second coating on the first coating, the second coating including metal oxide and stable carbon species; and
a third coating on the second coating the third coating including a hydrocarbon catalyst.

24. The coating system of claim 23 wherein the first coating consists essentially of metal oxide.

25. The coating system of claim 23 wherein the first coating is formed by oxidizing a constituent of the substrate.

26. The coating system of claim 23 wherein the first coating consists essentially of Cr₂O₃.

27. The coating system of claim 23 wherein the second coating consists essentially of metal oxide and stable carbon species with the balance being impurities.

28. The coating system of claim 23 wherein the second coating is formed by partial decomposition of an organometallic precursor effective to provide metal oxide and stable carbon species.

29. The coating system of claim 28 wherein the partial decomposition of an organometallic precursor is includes reacting oxygen with the organometallic precursor.

30. The coating system of claim 23 wherein the stable carbon species are effective to stabilize acid sites in the coating system.

31. The coating system of claim 23 wherein the stable carbon species are effective to inhibit diffusion of other carbon containing species through the coating system.

32. The coating system of claim 23 wherein the hydrocarbon catalyst includes platinum or palladium.

33. The coating system of claim 23 wherein the hydrocarbon catalyst includes a transition metal.

34. The coating system of claim 23 wherein the hydrocarbon catalyst is platinum.
